(19) United States
(12) Patent Application Publication
(10) Pub. No.: US 2026/0215082 A1
(43) Pub. Date: Jul. 23, 2026

(54) LIGHT-EMITTING ELEMENT, DISPLAY DEVICE, METHOD FOR MANUFACTURING LIGHT-EMITTING ELEMENT, AND METHOD FOR MANUFACTURING METAL-OXIDE NANOPARTICLES

(71) Applicant: Sharp Display Technology Corporation, Kameyama City, Mie (JP)

(72) Inventor: Yunting UEDA, Kameyama City, Mie (JP)

(21) Appl. No.: 19/158,148

(22) PCT Filed: Feb. 20, 2023
(86) PCT No.: PCT/JP2023/005936

§ 371 Date: Aug. 20, 2025

(51) Int. Cl. H10K 50/15; H10K 71/12

(52) U.S. Cl. CPC H10K 50/15; H10K 71/12

(57) ABSTRACT

A light-emitting element includes an anode; a cathode; a light-emitting layer provided between the anode and the cathode; and a charge transport layer provided between one of the anode or the cathode and the light-emitting layer, wherein the charge transport layer contains a plurality of metal-oxide nanoparticles free from surface oxygen-deficient portions, and one or more metal-oxide nanoparticles included in the plurality of metal-oxide nanoparticles have a surface at least partially provided with a coating portion formed of inorganic oxide.

### TECHNICAL FIELD

The present disclosure relates to a light-emitting element, a display device, a method for manufacturing the light-emitting element, and a method for manufacturing metal-oxide nanoparticles.

### BACKGROUND ART

In recent years, various display devices including light-emitting elements have been under development. In particular, display devices including organic light-emitting diodes (OLEDs) or quantum-dot light-emitting diodes (QLEDs) are significantly attracting attention because such display devices operate on lower power, have a thinner profile, and achieve higher image quality.

Because an OLED or a QLED is highly capable of transporting charges (transporting carriers; that is, holes or electrons), organic materials have been mainly used for such charge transport layers as a hole transport layer, a hole injection layer, an electron transport layer, and an electron injection layer.

However, the charge transport layers such as a hole transport layer, a hole injection layer, an electron transport layer, and an electron injection layer formed of the organic materials have a reliability problem.

Hence, researches are actively being carried out on inorganic materials that can be used for a charge transport layer of OLEDs or QLEDs.

Patent Document 1 discloses use of an inorganic material; that is, for example, nickel oxide nanocrystals (nanoparticles), for a charge transport layer.

### CITATION LIST

### Patent Literature

[Patent Document 1] Japanese Unexamined Patent Application Publication (Translation of PCT Application) No. 2019-522367

### SUMMARY

### Technical Problems

Typical metal-oxide nanoparticles at the manufacturing step develop a random number of surface oxygen-deficient portions (oxygen-deficient portions formed on a surface of the metal-oxide nanoparticles because of lack of molecular interactions) at random positions on the surface of the metal-oxide nanoparticles. The surface oxygen-deficient portions affect, and change, an energy level, such that the energy level inevitably varies for each of the metal-oxide nanoparticles. Hence, if a light-emitting element includes a charge transport layer formed of such metal-oxide nanoparticles whose surface has the surface oxygen-deficient portions, the light-emitting element has a problem of a decrease in light emission efficiency accompanied by a decrease in external quantum efficiency (EQE).

Patent Document 1 describes a light-emitting element including a charge transport layer. The charge transport layer contains: nickel-oxide nanocrystals (nanoparticles) as metal-oxide nanoparticles; and organic molecules having electron-attracting groups.

However, the surface oxygen-deficient portions are still left on the nickel-oxide nanocrystals (nanoparticles) contained in the charge transport layer included in the light-emitting element described in Patent Document 1. Hence, the light-emitting element cannot reduce the decrease in light emission efficiency described above. Furthermore, the light-emitting element has a reliability problem because of the use of organic molecules including the electron-attracting groups.

An aspect of the present disclosure is conceived in view of the above problems, and sets out to provide a light-emitting element successfully achieving high reliability and reducing a decrease in light emission efficiency accompanied by a decrease in external quantum efficiency (EQE). The aspect sets out to also provide a display device, a method for manufacturing the light-emitting element, and a method for manufacturing metal-oxide nanoparticles.

### Solution to Problems

In order to solve the above problems, a light-emitting element according to the present disclosure includes:
an anode;
a cathode;
a light-emitting layer provided between the anode and the cathode; and
a charge transport layer provided between one of the anode or the cathode and the light-emitting layer.

The charge transport layer contains a plurality of metal-oxide nanoparticles free from surface oxygen-deficient portions.

One or more metal-oxide nanoparticles included in the plurality of metal-oxide nanoparticles have a surface at least partially provided with a coating portion formed of inorganic oxide.

In order to solve the above problems, a display device according to the present disclosure includes
the light-emitting element.

In order to solve the above problems, a method for manufacturing a light-emitting element according to the present disclosure includes
a step of forming a charge transport layer including: a step of providing a coating portion, containing inorganic oxide, to a surface of each of a plurality of metal-oxide nanoparticles; and
after the step of providing the coating portion, a step of heat-treating the plurality of metal-oxide nanoparticles under an oxygen atmosphere.

In order to solve the above problems, a method for manufacturing metal-oxide nanoparticles according to the present disclosure includes:
a step of providing a coating portion, containing inorganic oxide, to a surface of each of a plurality of metal-oxide nanoparticles; and
after the step of providing the coating portion, a step of heat-treating the plurality of metal-oxide nanoparticles under an oxygen atmosphere.

### Advantageous Effects of Disclosure

An aspect of the present disclosure provides a light-emitting element successfully achieving high reliability and reducing a decrease in light emission efficiency accompanied by a decrease in external quantum efficiency (EQE). The aspect also provides a display device, a method for manufacturing the light-emitting element, and a method for manufacturing metal-oxide nanoparticles.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a display region of the display device according to the first embodiment.

FIG. 3 is a flowchart showing a step of manufacturing the display device according to the first embodiment including steps of manufacturing a red light-emitting element, a green light-emitting element, and a blue light-emitting element.

FIG. 4 is a cross-sectional view illustrating a schematic configuration of the red light-emitting element included in the display device according to the first embodiment.

FIG. 5 is a cross-sectional view of a schematic configuration of the green light-emitting element included in the display device according to the first embodiment.

FIG. 6 is a cross-sectional view of a schematic configuration of the blue light-emitting element included in the display device according to the first embodiment.

FIG. 7 is a flowchart showing steps of forming the functional layers in the step of manufacturing the display device according to first embodiment in FIG. 3.

FIG. 8 is a flowchart showing a step of manufacturing nickel-oxide nanoparticles as metal-oxide nanoparticles having surface oxygen-deficient portions.

FIG. 9 is a flowchart showing a step of providing a coating portion, containing inorganic oxide, to a surface of each of a plurality of the nickel-oxide nanoparticles manufactured at the step of manufacturing nickel-oxide nanoparticles, and, after the step of providing the coating portion, a step of heat-treating the plurality of nickel-oxide nanoparticles under an oxygen atmosphere and a step of removing the coating portion.

FIG. 10 illustrates a schematic condition of the nickel-oxide nanoparticles at each of the steps in FIG. 9.

FIG. 11 is a cross-sectional view illustrating a schematic configuration of a hole transport layer serving as a charge transport layer included in each of the red light-emitting element, the green light-emitting element, and the blue light-emitting element included in the display device according to the first embodiment.

FIG. 12 is a cross-sectional view illustrating a schematic configuration of a red light-emitting element included in a display device according to a second embodiment.

FIG. 13 is a cross-sectional view illustrating a schematic configuration of an electron transport layer serving as a charge transport layer included in the red light-emitting element in FIG. 12.

FIG. 14 is a cross-sectional view illustrating a schematic configuration of a red light-emitting element included in a display device according to a third embodiment.

### DESCRIPTION OF EMBODIMENTS

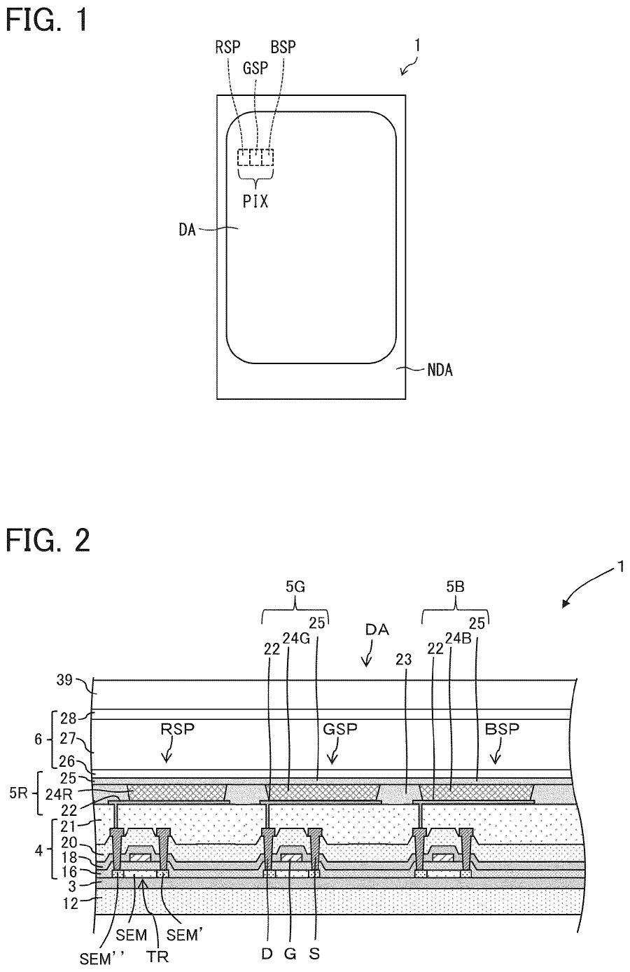

Described below are embodiments of the disclosure, with reference to FIGS. 1 to 14. For convenience in description, like reference signs designate identical constituent features throughout the embodiments. These constituent features will not be elaborated upon.

### First Embodiment

FIG. 1 is a plan view illustrating a schematic configuration of a display device 1 according to a first embodiment.

As illustrated in FIG. 1, the display device 1 includes a picture-frame region NDA and a display region DA. The display region DA of the display device 1 includes a plurality of pixels PIX. Each of the pixels PIX includes a red subpixel RSP, a green subpixel GSP, and a blue subpixel BSP. This embodiment exemplifies a case where one pixel PIX includes the red subpixel RSP, the green subpixel GSP, and the blue subpixel BSP. However, this embodiment shall not be limited to such a case. For example, the one pixel PIX may further include a subpixel in another color, in addition to the red subpixel RSP, the green subpixel GSP, and the blue subpixel BSP.

FIG. 2 is a cross-sectional view illustrating a schematic configuration of the display region DA of the display device 1 according to the first embodiment.

As illustrated in FIG. 2, the display region DA of the display device 1 includes: a barrier layer 3; a thin-film transistor layer 4 including a transistor TR; a red light-emitting element 5R, a green light-emitting element 5G, a blue light-emitting element 5B, and a bank 23; a sealing layer 6; and a functional film 39, all of which are provided in the stated order above, and from toward, a substrate 12.

The red subpixel RSP provided to the display region DA of the display device 1 includes the red light-emitting element 5R serving as a light-emitting element. The green subpixel GSP provided to the display region DA of the display device 1 includes the green light-emitting element 5G serving as a light-emitting element. The blue subpixel BSP provided to the display region DA of the display device 1 includes the blue light-emitting element 5B serving as a light-emitting element.

The substrate 12 may be, for example, either a resin substrate made of a resin material such as polyimide, or a glass substrate. This embodiment exemplifies a case where the display device 1 is a flexible display device, and the substrate 12 is, for example, a resin substrate made of a resin material such as polyimide. However, this embodiment shall not be limited to such a case. If the display device 1 is an inflexible display device, the substrate 12 may be, for example, a glass substrate.

The barrier layer 3 is a layer that prevents foreign substances such as water and oxygen from entering the transistor TR, the red light-emitting element 5R, the green light-emitting element 5G, and the blue light-emitting element 5B. For example, the barrier layer 3 may be a silicon oxide film, a silicon nitride film, or a silicon oxynitride film formed by the CVD. Alternatively, the barrier layer 3 may be a multilayer film including these films.

The thin-film transistor layer 4 including the transistor TR has a transistor TR portion. The transistor TR portion includes: a semiconductor film SEM; doped semiconductor films SEM′ and SEM′; an inorganic insulating film 16; a gate electrode G; an inorganic insulating film 18; an inorganic insulating film 20; a source electrode S; a drain electrode D; and a planarization film 21. The thin-film transistor layer 4 including the transistor TR has a portion other than the transistor TR portion. The other portion includes: the inorganic insulating film 16; the inorganic insulating film 18; the inorganic insulating film 20; and the planarization film 21.

The semiconductor films SEM, SEM′, and SEM″ may be formed of, for example, low-temperature polysilicon (LTPS) or an oxide semiconductor (e.g., an In—Ga—Zn—O-based semiconductor). This embodiment exemplifies a case where the transistor TR is a top-gate transistor. However, this embodiment shall not be limited to such a case. The transistor TR may be a bottom-gate transistor.

Each of the gate electrode G, the source electrode S, and the drain electrode D can be, for example, a metal monolayer film containing at least one of aluminum, tungsten, molybdenum, tantalum, chromium, titanium, or copper. Alternatively, each electrode can be a metal multilayer film containing these metals.

Each of the inorganic insulating film 16, the inorganic insulating film 18, and the inorganic insulating film 20 can be, for example, a silicon oxide film, a silicon nitride film, or a silicon oxynitride film formed by the CVD. Alternatively, each of the inorganic insulating films 16, 18, and 20 can be a multilayer film including these films.

The planarization film 21 may be formed of, for example, an applicable organic material such as polyimide or acrylic.

The red light-emitting element 5R included in the red subpixel RSP includes: an anode 22 provided above the planarization film 21; a functional layer 24R including a red light-emitting layer; and a cathode 25. The green light-emitting element 5G included in the green subpixel GSP includes: an anode 22 provided above the planarization film 21; a functional layer 24G including a green light-emitting layer; and the cathode 25. The blue light-emitting element 5B included in the blue subpixel BSP includes: an anode 22 provided above the planarization film 21; a functional layer 24B including a blue light-emitting layer; and the cathode 25. Note that the bank 23, which is insulative and covers an edge of each anode 22, can be formed of such an organic material as, for example, polyimide or acrylic. The organic material is applied and, after that, patterned by photolithography to form the bank 23.

This embodiment exemplifies a case where the functional layer 24R including the red light-emitting layer has: the hole transport layer; the red light-emitting layer; and the electron transport layer, all of which are stacked on top of another in the stated order from toward an anode 22. However, this embodiment shall not be limited to such a case. The functional layer 24R including the red light-emitting layer may include, for example: the hole injection layer; the hole transport layer; the red light-emitting layer; the electron transport layer; and the electron injection layer, all of which are stacked on top of another in the stated order from toward the anode 22. For example, the functional layer 24R may include: the red light-emitting layer; and one or more of such charge transport layers as the hole injection layer, the hole transport layer, the electron transport layer, and the electron injection layer.

This embodiment exemplifies a case where the functional layer 24G including the green light-emitting layer includes: the hole transport layer; the green light-emitting layer; and the electron transport layer, all of which are stacked on top of another in the stated order from toward an anode 22. However, this embodiment shall not be limited to such a case. The functional layer 24G including the green light-emitting layer may include, for example: the hole injection layer; the hole transport layer; the green light-emitting layer; the electron transport layer; and the electron injection layer, all of which are stacked on top of another in the stated order from toward the anode 22. For example, the functional layer 24G may include: the green light-emitting layer; and one or more of such charge transport layers as the hole injection layer, the hole transport layer, the electron transport layer, and the electron injection layer.

This embodiment exemplifies a case where the functional layer 24B including the blue light-emitting layer includes: the hole transport layer; the blue light-emitting layer; and the electron transport layer, all of which are stacked on top of another in the stated order from toward an anode 22. However, this embodiment shall not be limited to such a case. The functional layer 24B including the blue light-emitting layer may include, for example: the hole injection layer; the hole transport layer; the blue light-emitting layer; the electron transport layer; and the electron injection layer, all of which are stacked on top of another in the stated order from toward the anode 22. For example, the functional layer 24B may include: the blue light-emitting layer; and one or more of such charge transport layers as the hole injection layer, the hole transport layer, the electron transport layer, and the electron injection layer.

This embodiment exemplifies a case where the functional layer 24R including the red light-emitting layer, the functional layer 24G including the green light-emitting layer, and the functional layer 24B including the blue light-emitting layer include: respective hole transport layers formed of the same material at the same step; and respective electron transport layers formed of the same material at the same step. However, this embodiment shall not be limited to such a case.

For example, the hole transport layers included in the respective functional layers 24R, 24G, and 24B may be formed of materials different from one another. For example, the hole transport layers included in two of the functional layers 24R, 24G, and 24B may be formed of the same material at the same step, and the hole transport layer included in the remaining one functional layer alone may be formed of a different material at a separate step.

Moreover, for example, the electron transport layers included in the respective functional layers 24R, 24G, and 24B may be formed of materials different from one another. For example, the electron transport layers included in two of the functional layers 24R, 24G, and 24B may be formed of the same material at the same step, and the electron transport layer included in the remaining one functional layer alone may be formed of a different material at a separate step.

This embodiment exemplifies a case where each of the red light-emitting element 5R, the green light-emitting element 5G, and the blue light-emitting element 5B is a quantum-dot light-emitting diode (a QLED) including a light-emitting layer containing quantum dots. However, this embodiment shall not be limited to such a case. Each of the red light-emitting element 5R, the green light-emitting element 5G, and the blue light-emitting element 5B may be an organic light-emitting diode (an OLED) including an organic light-emitting layer. Furthermore, one or more of the red light-emitting element 5R, the green light-emitting element 5G, and the blue light-emitting element 5B may be QLEDs, and the remaining one or more of the red light-emitting element 5R, the green light-emitting element 5G, and the blue light-emitting element 5B may be OLEDs.

A control circuit including a transistor TR that controls the red light-emitting element 5R, a control circuit including a transistor TR that controls the green light-emitting element 5G, and a control circuit including a transistor TR that controls the blue light-emitting element 5B are provided to the thin-film transistor layer 4 including the transistors TR for the respective red subpixel RSP, green subpixel GSP, and blue subpixel BSP. Note that a light-emitting element and a control circuit, which includes a transistor TR provided for each of the red subpixel RSP, the green subpixel GSP, and the blue subpixel BSP, are collectively referred to as a subpixel circuit.

The red light-emitting element 5R, the green light-emitting element 5G, and the blue light-emitting element 5B illustrated in FIG. 2 may be either top-emission light-emitting elements or bottom-emission light-emitting elements. Each of the red light-emitting element 5R, the green light-emitting element 5G, and the blue light-emitting element 5B has the forward-order stack structure in which the anode 22, each of the functional layers 24R, 24G, and 24B, and the cathode 25 are formed in the stated order from toward the substrate 12. Hence, the cathode 25 is disposed above the anode 22. If each light-emitting element is to be formed as a top-emission light-emitting element, the anode 22 may be formed of an electrode material reflective to visible light, and the cathode 25 may be formed of an electrode material transparent to visible light. If each light-emitting element is to be formed as a bottom-emission light-emitting element, the anode 22 may be formed of an electrode material transparent to visible light, and the cathode 25 may be formed of an electrode material reflective to visible light.

Although not shown, each of the red light-emitting element 5R, the green light-emitting element 5G, and the blue light-emitting element 5B may have the reverse-order stack structure in which the cathode 25, each of the functional layers (e.g., the electron transport layer, the light-emitting layer, and the hole transport layer are stacked on top of another in the stated order from toward the substrate 12), and the anode 22 are formed in the stated order from toward the substrate 12. Hence, in the case of the reverse-order stack structure, the anode 22 is disposed above the cathode 25. If each light-emitting element is to be formed as a top-emission light-emitting element, the cathode 25 may be formed of an electrode material reflective to visible light, and the anode 22 may be formed of an electrode material transparent to visible light. If each light-emitting element is to be formed as a bottom-emission light-emitting element, the cathode 25 may be formed of an electrode material transparent to visible light, and the anode 22 may be formed of an electrode material reflective to visible light.

The electrode material reflective to visible light may be any given material as long as the material can reflect visible light and conduct electricity. Examples of the electrode material include: a metal material such as Al, Mg, Li, or Ag; an alloy of the metal materials; a multilayer stack of the metal material and a transparent metal oxide (e.g., indium tin oxide, indium zinc oxide, or indium gallium zinc oxide); or a multilayer stack of the alloy and the transparent metal oxide.

Whereas, the electrode material transparent to visible light may be any given material as long as the material can transmit visible light and conduct electricity. Examples of the electrode material include: a transparent metal oxide (e.g., indium tin oxide, indium zinc oxide, or indium gallium zinc oxide); a thin film formed of a metal material such as Al or Ag; or nano wires formed of a metal material such as Al or Ag.

This embodiment exemplifies a case where each of the red light-emitting element 5R, the green light-emitting element 5G, and the blue light-emitting element 5B is a top-emission light-emitting element having the forward-order stack structure. Hence, the anode 22 is formed of a multilayer film containing electrode materials such as indium tin oxide (ITO)/Ag/ITO reflective to visible light, and the cathode 25 is formed of a thin film made of an electrode material such as Ag transparent to visible light. However, this embodiment shall not be limited to such a case.

The sealing layer 6 is a light-transparent film. The sealing layer 6 includes, for example: an inorganic sealing film 26 covering the cathode 25; an organic film 27 above the inorganic sealing film 26; and an inorganic sealing film 28 above the organic film 27. The sealing layer 6 prevents foreign substances such as water and oxygen from penetrating into the red light-emitting element 5R, the green light-emitting element 5G, and the blue light-emitting element 5B.

Each of the inorganic sealing film 26 and the inorganic sealing film 28 is an inorganic film. For example, the inorganic film can be a silicon oxide film, a silicon nitride film, or a silicon oxynitride film formed by the CVD. Alternatively, the inorganic film can be a multilayer film including these films. The organic film 27 is a light-transparent organic film exhibiting a planarizing effect. The organic film 27 can be made of, for example, an applicable organic material such as acrylic. The organic film 27 may be formed by, for example, inkjet printing. This embodiment exemplifies a case where the sealing layer 6 is formed of two inorganic films and one organic film provided between the two inorganic films. However, the two inorganic films and the one organic film may be stacked in any given order. Furthermore, the sealing layer 6 may be formed of an inorganic film alone, may be formed of one inorganic film and two organic films, or may be formed of two or more inorganic films and two or more organic films.

The functional film 39 has at least one of, for example, an adaptive optics correction function, a touch sensor function, or a protection function.

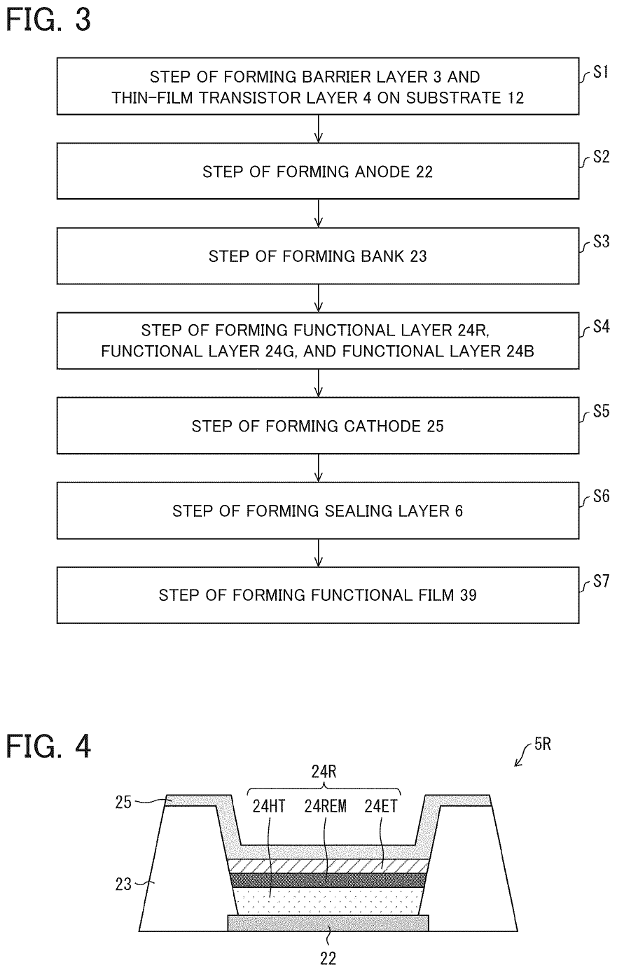

FIG. 3 is a flowchart showing a step of manufacturing the display device 1 according to the first embodiment including steps of manufacturing the red light-emitting element 5R, the green light-emitting element 5G, and the blue light-emitting element 5B.

The display device 1 illustrated in FIG. 2 includes light-emitting elements each having the forward-order stack structure. As shown in FIG. 3, the step of manufacturing the display device 1 includes: a step of forming the barrier layer 3 and the thin-film transistor layer 4 (S1); a step of forming the anode 22 (S2), a step of forming the bank 23 (S3); a step of forming the functional layer 24R including the red light-emitting layer included in the red light-emitting element 5R, the functional layer 24G including the green light-emitting layer included in the green light-emitting element 5G, and the functional layer 24B including the blue light-emitting layer included in the blue light-emitting element 5B (S4); a step of forming the cathode 25 (S5); a step of forming the sealing layer 6 (S6), and the step of forming the functional film 39 (S7). Here, all of the constituent elements are provided above the substrate 12. Whereas, although not shown, a step of manufacturing a display device including light-emitting elements in the reverse-order stack structure is the same as the step of manufacturing the display device 1 including the light-emitting elements in the forward-order stack structure illustrated in FIG. 3, except for a change in the order of the step of forming the anode 22 (S2) and the step of forming the cathode 25 (S5).

FIG. 4 is a cross-sectional view of a schematic configuration of the red light-emitting element 5R included in the display device 1 according to the first embodiment.

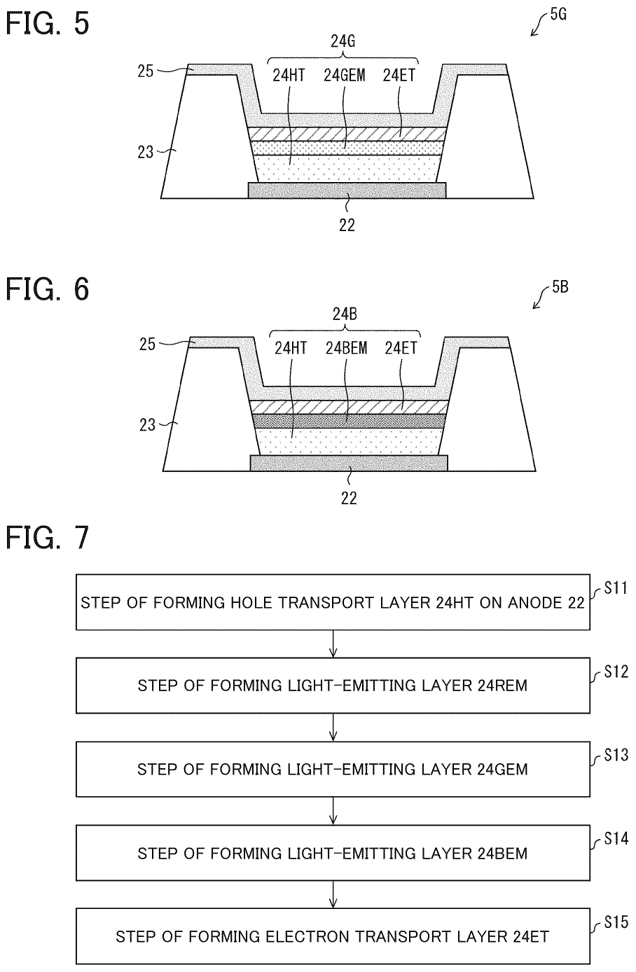

FIG. 5 is a cross-sectional view of a schematic configuration of the green light-emitting element 5G included in the display device 1 according to the first embodiment.

FIG. 6 is a cross-sectional view of a schematic configuration of the blue light-emitting element 5B included in the display device 1 according to the first embodiment.

FIG. 7 is a flowchart showing steps of forming the functional layers 24R, 24G, and 24B in the step of manufacturing the display device 1 according to first embodiment in FIG. 3.

As shown in FIG. 7, the steps of forming the functional layer 24R included in the red light-emitting element 5R, the functional layer 24G included in the green light-emitting element 5G, and the functional layer 24B included in the blue light-emitting element 5B include: a step of forming a hole transport layer 24HT on the anode 22 (S11); a step of forming a light-emitting layer 24REM (the red light-emitting layer) (S12); a step of forming a light-emitting layer 24GEM (the green light-emitting layer) (S13); a step of forming a light-emitting layer 24BEM (the blue light-emitting layer) (S14); and a step of forming an electron transport layer 24ET (S15).

This embodiment exemplifies a case where the light-emitting layer 24REM (the red light-emitting layer), the light-emitting layer 24GEM (the green light-emitting layer), and the light-emitting layer 24BEM (the blue light-emitting layer) are formed in the stated order. However, this embodiment shall not be limited to such a case. These light-emitting layers may be formed in any given order.

In this embodiment, as described above, the functional layers 24R, 24G, and 24B include the hole transport layers 24HT formed of the same material at the same step. Hence, at the step of forming the hole transport layer 24HT on the anode 22 (S11), as illustrated in FIGS. 4, 5, and 6, the hole transport layer 24HT is formed on the anode 22 included in each of the red light-emitting element 5R, the green light-emitting element 5G, and the blue light-emitting element 5B.

Furthermore, in this embodiment, as described above, the functional layers 24R, 24G, and 24B include the electron transport layers 24ET formed of the same material at the same step. Hence, at the step of forming the electron transport layer 24ET (S15), as illustrated in FIGS. 4, 5, and 6, the electron transport layer 24ET is formed on each of the light-emitting layer 24REM (the red light-emitting element) included the red light-emitting element 5R, the light-emitting layer 24GEM (the green light-emitting element) included the green light-emitting element 5G, and the light-emitting layer 24BEM (the blue light-emitting element) included the blue light-emitting element 5B.

Note that the anode 22 may be formed to have a thickness of, for example, 100 nm or more and 300 nm or less. However, the thickness shall not be limited to such an example. The cathode 25 may be formed to have a thickness of, for example, 10 nm or more and 100 nm or less. However, the thickness shall not be limited to such an example. The hole transport layer 24HT may be formed to have a thickness of, for example, 10 nm or more and 150 nm or less. However, the thickness shall not be limited to such an example. The light-emitting layer 24REM (the red light-emitting layer), the light-emitting layer 24GEM (the green light-emitting layer) and the light-emitting layer 24BEM (the blue light-emitting layer) may be formed to have a thickness of, for example, 20 nm or more and 50 nm or less. However, the thickness shall not be limited to such an example. The electron transport layer 24ET may be formed to have a thickness of, for example, 30 nm or more and 120 nm or less. However, the thickness shall not be limited to such an example.

Note that, in this embodiment, the electron transport layer 24ET can be formed of, for example, zinc-oxide nanoparticles having surface oxygen-deficient portions DE.

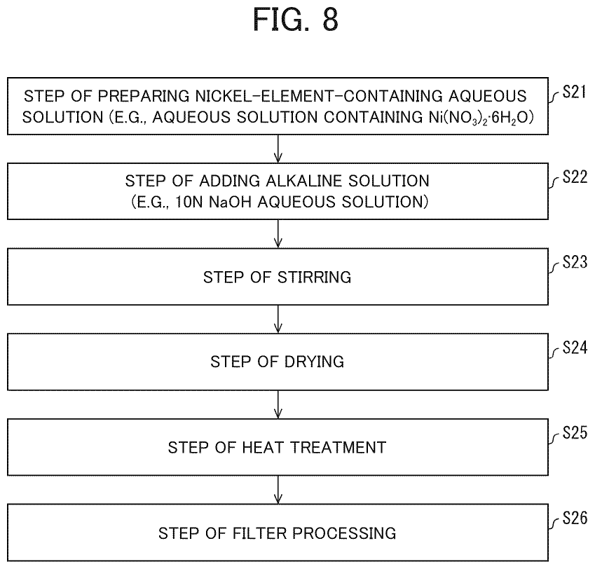

With reference to FIGS. 8 to 11, described below will be a method for manufacturing nickel-oxide nanoparticles as metal-oxide nanoparticles to be used at the step of forming the hole transport layer 24HT on the anode 22 (S11).

This embodiment exemplifies a case where nickel-oxide nanoparticles are an example of metal-oxide nanoparticles to be used at the step of forming the hole transport layer 24HT on the anode 22. However, the metal-oxide nanoparticles may be any given ones as long as the metal-oxide nanoparticles are a hole transport material to be used at a step of forming at least one of the hole transport layer 24HT or the hole injection layer that are provided between the anode 22 and the light-emitting layers 24REM, 24GEM, and 24BEM. For example, the metal-oxide nanoparticles serving as a hole transport material may be metal-oxide nanoparticles containing at least one of Ni, Mg, Mo, Cu, Co, Cr, or Ti.

Furthermore, as will be described in a second embodiment (see FIG. 12), the metal-oxide nanoparticles may be ones serving as an electron transport material to be used at a step of forming at least one of an electron transport layer 24ET′ or the electron injection layer that are provided between the cathode 25 and the light-emitting layer 24REM. For example, the metal-oxide nanoparticles serving as an electron transport material may be metal-oxide nanoparticles containing at least one of Zn, Mg, Ti, Si, Sn, W, Ta, Ba, Zr, Al, Y, or Hf. For example, the metal-oxide nanoparticles serving as an electron transport material may be either zinc-oxide nanoparticles or magnesium-zinc-oxide nanoparticles.

Note that the metal-oxide nanoparticles may have any given particle size. The particle size is preferably, for example, 1 nm or more and 1000 nm or less. Because the metal-oxide nanoparticles have a particle size of 1 nm or more, the particle size of the metal-oxide nanoparticles is readily controlled. Furthermore, because the metal-oxide nanoparticles have a particle size of 1000 nm or less, improvements can be observed in injection of holes from the anode 22 or injection of electrons from the cathode 25.

FIG. 8 is a flowchart showing a step of manufacturing the nickel-oxide nanoparticles NP as metal-oxide nanoparticles having the surface oxygen-deficient portions DE.

As illustrated in FIG. 8, the step of manufacturing the nickel-oxide nanoparticles NP as metal-oxide nanoparticles having the surface oxygen-deficient portions DE includes: a step of preparing a nickel-element-containing aqueous solution (S21); a step of adding an alkaline solution (S22); a step of stirring (S23); a step of drying (S24); a step of heat treatment (S25); and a step of filter processing (S26).

At the step of preparing a nickel-element-containing aqueous solution (S21), for example, a nickel-element-containing aqueous solution is prepared to have 7.27 g of Ni(NO₃)₂·6H₂O dispersed in 10 ml of pure water. After that, at the step of adding an alkaline solution (S22), for example, 5.85 to 5.9 ml of a 10N (N represents normality) NaOH aqueous solution is added. The NaOH aqueous solution may be stirred at a speed of, for example, 0.3 to 0.4 ml/min and added until the PH reaches approximately 10. After that, at the step of stirring, (S23), the mixture is stirred for approximately five minutes. Through the above steps, nickel-oxide nanoparticles can be obtained by a chemical precipitation technique in an alkaline environment. Prior to the step of drying (S24), a step of rinsing may be carried out to rinse the nickel-oxide nanoparticles. After that, at the step of drying (S24), the nickel-oxide nanoparticles are heat-treated and dried, for example, at 80° C. for 15 to 24 hours. After that, a step of pulverizing the nickel-oxide nanoparticles may be carried out as necessary. After that, at the step of heat treatment (S25), for example, the nickel-oxide nanoparticles are heat-treated and fired at 250° C. to 270° C. in the presence of oxygen for 2 to 4 hours. After that, at the step of filter processing (S26), the fired nickel-oxide nanoparticles are pulverized. Then, the pulverized nickel-oxide nanoparticles are put in pure water, stirred, and dispersed. After that, the mixture is filtered through a PTFE filter with holes having a diameter of 1 μm. Hence, obtained are nickel-oxide nanoparticles having a particle size of 1000 nm or less.

In a case of the nickel-oxide nanoparticles NP manufactured at the step of manufacturing the nickel-oxide nanoparticles NP shown in FIG. 8, lack of molecular interactions observed on a surface SU of the nickel-oxide nanoparticles NP inevitably develops the surface oxygen-deficient portions DE on the surface SU. The surface oxygen-deficient portions DE are oxygen-deficient portions formed on the surface of the metal-oxide nanoparticles because of lack of molecular interactions on the surface.

This embodiment exemplifies a case of the nickel-oxide nanoparticles NP manufactured at the step of manufacturing the nickel-oxide nanoparticles NP shown in FIG. 8. However, this embodiment shall not be limited to such a case. In a case of nickel-oxide nanoparticles manufactured at a step of manufacturing typically known nickel-oxide nanoparticles, it is known that these surface oxygen-deficient portions DE inevitably develop. Furthermore, this embodiment shall not be limited to the nickel-oxide nanoparticles. In a case of metal-oxide nanoparticles (e.g., such nanoparticles as zinc-oxide nanoparticles or magnesium-zinc-oxide nanoparticles), it is known that these surface oxygen-deficient portions DE inevitably develop.

As to the nickel-oxide nanoparticles NP manufactured at the step of manufacturing the nickel-oxide nanoparticles NP shown in FIG. 8, the surface oxygen-deficient portions DE are formed at random positions in a random number on the surface SU of the nickel-oxide nanoparticles NP. The surface oxygen-deficient portions DE affect, and change, an energy level. Hence, if a light-emitting element includes a charge transport layer formed of the nickel-oxide nanoparticles NP that inevitably exhibit variations in the energy level for each of the nickel-oxide nanoparticles NP, a problem occurs; that is, a decrease in light emission efficiency accompanied by a decrease in external quantum efficiency (EQE).

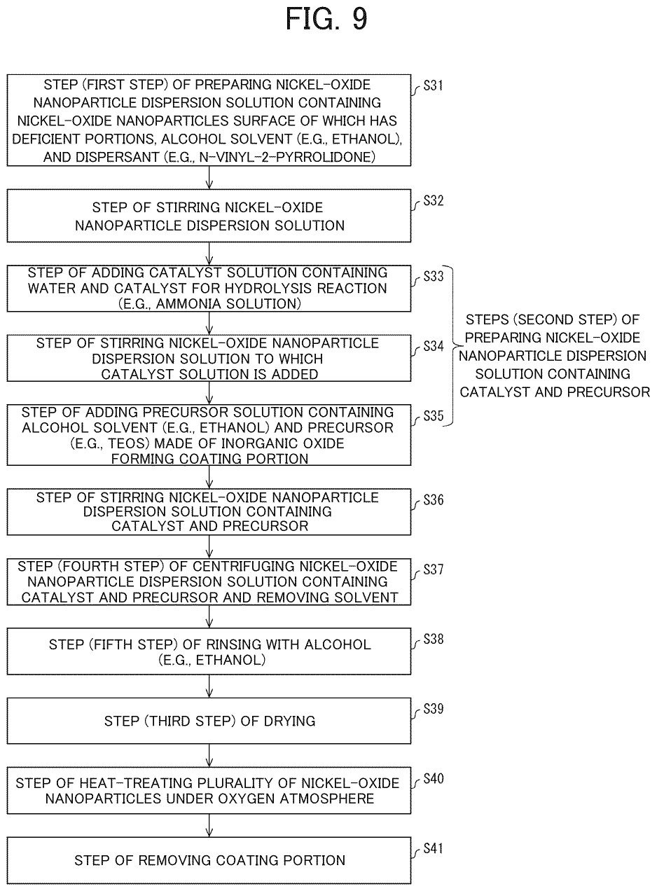

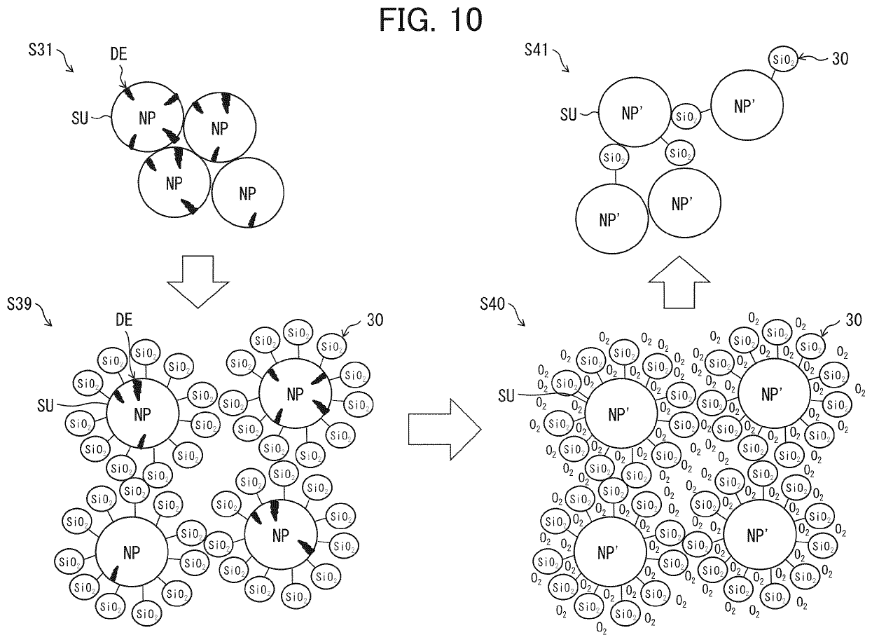

FIG. 9 is a flowchart showing steps of providing a coating portion 30 (S31 to S39), containing inorganic oxide, to the surface SU of each of the plurality of nickel-oxide nanoparticles NP manufactured at the step of manufacturing the nickel-oxide nanoparticles NP, and, after the steps of providing the coating portion 30, a step of heat-treating the plurality of nickel-oxide nanoparticles NP (S40) under an oxygen atmosphere, and a step of removing the coating portion 30 (S41).

FIG. 10 illustrates a schematic condition of the nickel-oxide nanoparticles NP and NP′ at each of the steps in FIG. 9.

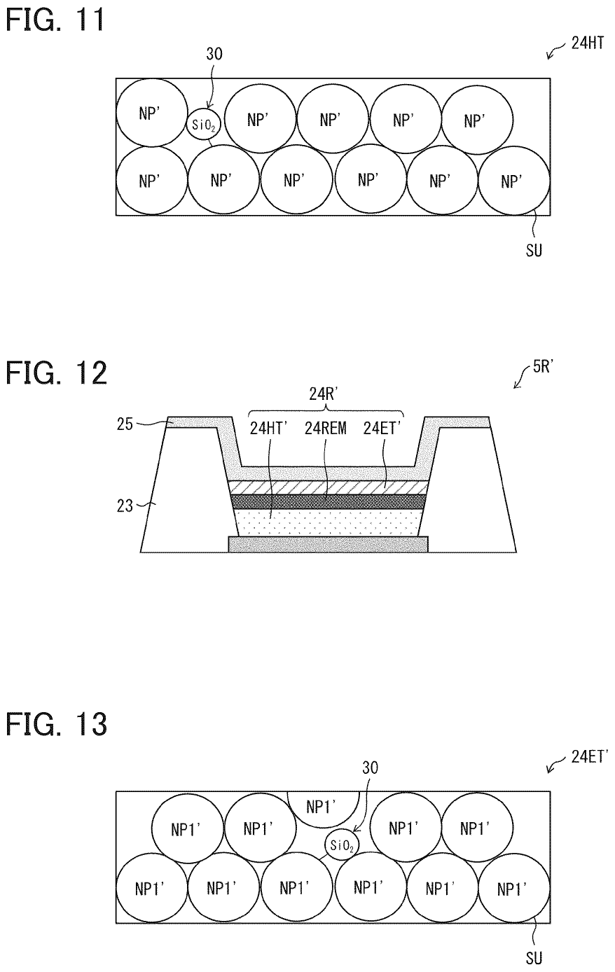

FIG. 11 is a cross-sectional view illustrating a schematic configuration of the hole transport layer 24HT serving as a charge transport layer included in each of the red light-emitting element 5R, the green light-emitting element 5G, and the blue light-emitting element 5B included in the display device 1 according to the first embodiment.

Hence, as illustrated in FIG. 10, this embodiment provides a method for manufacturing the nickel-oxide nanoparticles NP′. The method includes: the steps of providing the coating portion 30 (S31 to S39), containing inorganic oxide, to the surface SU of the nickel-oxide nanoparticles NP as a plurality of metal-oxide nanoparticles, the surface SU having the surface oxygen-deficient portions DE; and, after the steps of providing the coating portion 30, the step of heat-treating the nickel-oxide nanoparticles NP (S40) under an oxygen atmosphere. As a result, the obtained nickel-oxide nanoparticles NP′ as a plurality of metal-oxide nanoparticles are successfully free from the surface oxygen-deficient portions DE.

The method for manufacturing the nickel-oxide nanoparticles NP′ described above can provide the nickel-oxide nanoparticles NP′ as metal-oxide nanoparticles. The nickel-oxide nanoparticles NP′ include the coating portion 30 formed of inorganic oxide, thereby achieving high reliability. Furthermore, the nickel-oxide nanoparticles NP′ are free from the surface oxygen-deficient portions DE, thereby successfully reducing a decrease in light emission efficiency accompanied by a decrease in external quantum efficiency (EQE).

Moreover, the method for manufacturing the nickel-oxide nanoparticles NP′ described above may preferably include the step of removing the coating portion 30 after the step of heat-treating (S40).

Compared with a degree of change in the energy level of the metal-oxide nanoparticles because of influence of the surface oxygen-deficient portions DE formed at random positions in a random number on the surface of the metal-oxide nanoparticles, only a small degree of change is observed in the energy level of the metal-oxide nanoparticles because of influence of the coating portion 30 formed of inorganic oxide that is oxide similar to the metal-oxide nanoparticles. Hence, at the step of removing the coating portion 30 (S41), the coating portion 30 formed of inorganic oxide may be removed. However, the coating portion 30, which is formed of inorganic oxide that reduces agglomeration of the nickel-oxide nanoparticles NP′ themselves, may be partially left unremoved. Alternatively, the step of removing the coating portion 30 (S41) may be omitted, and the coating portion 30 formed of inorganic oxide may be entirely left unremoved.

The method for manufacturing light-emitting elements (the red light-emitting element 5R, the green light-emitting element 5G, and the blue light-emitting element 5B) included in the display device 1 described above includes the step of forming the hole transport layer 24HT serving as a charge transport layer. The step of forming the hole transport layer 24HT includes the steps of providing the coating portion 30 (S31 to S39) containing inorganic oxide, and, after the steps of providing the coating portion 30, the step of heat-treating the nickel-oxide nanoparticles NP (S40) under an oxygen atmosphere.

Furthermore, after the step of heat-treating (S40), the step of forming the hole transport layer 24HT preferably includes the step of removing the coating portion 30 (S41).

As shown in FIG. 9, the steps (S31 to S39) of providing the coating portion 30 containing inorganic oxide include: a step of preparing a nickel-oxide nanoparticle dispersion solution (S31, a first step); a step of stirring the nickel-oxide nanoparticle dispersion solution (S32); a step of adding a catalyst solution containing water and a catalyst for hydrolysis reaction (S33); a step of stirring the nickel-oxide nanoparticle dispersion solution to which the catalyst solution is added (S34); a step of adding a precursor solution containing an alcohol solvent and a precursor made of the inorganic oxide forming the coating portion 30 (S35); a step of stirring the nickel-oxide nanoparticle dispersion solution containing the catalyst and the precursor (S36); a step of centrifuging the nickel-oxide nanoparticle dispersion solution containing the catalyst and the precursor and removing the solvent (S37, a fourth step); a step of rinsing with alcohol (S38, a fifth step); and a step of drying (S39, a third step).

At the step of preparing the nickel-oxide nanoparticle dispersion solution (S31), for example, the nickel-oxide nanoparticles NP, the surface SU of which has the surface oxygen-deficient portions DE, are put into one litter of ethanol; that is, an alcohol solvent containing 10 g of N-vinyl-2-pyrrolidone serving as a dispersant. At the step of stirring the nickel-oxide nanoparticle dispersion solution (S32), the nickel-oxide nanoparticle dispersion solution is stirred for, for example, 12 hours. At the step of adding a catalyst solution containing water and a catalyst for hydrolysis reaction (S33), for example, 100 ml of water and a 25% ammonia solution containing 25 wt % of NH₃ to the 100 ml of water are added. This embodiment exemplifies a case where the catalyst for hydrolysis reaction is a base catalyst. Alternatively, the catalyst for hydrolysis reaction may be an acid catalyst. At the step of stirring the nickel-oxide nanoparticle dispersion solution to which the catalyst solution is added (S34), for example, the nickel-oxide nanoparticle dispersion solution is stirred for, for example, 30 minutes, using ultrasonic waves. At the step of adding the precursor solution containing the alcohol solvent and the precursor of the inorganic oxide forming the coating portion 30 (S35), for example, 50 ml of the precursor solution is added. The precursor solution contains 49 ml of ethanol as an alcohol solvent and 1 ml of tetraethoxysilane (TEOS) as the precursor of the inorganic oxide forming the coating portion 30. This embodiment exemplifies a case where tetraethoxysilane (TEOS) is used as the precursor made of the inorganic oxide forming the coating portion 30. However, this embodiment shall not be limited to this case. The precursor may be the one represented by Chemical Formula (1) below.

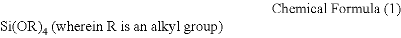

Furthermore, the precursor of the inorganic oxide forming the coating portion 30 may be the one represented by Chemical Formula (2) below.

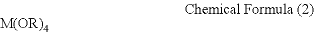

Wherein, in Chemical Formula (2), M is either a metal element or a half metal element other than Si, and R is an alkyl group.

Note that the steps S33 to S35 described above are those of preparing the nickel-oxide nanoparticle dispersion solution (sol) containing a catalyst and a precursor (a second step).

At the step of stirring the nickel-oxide nanoparticle dispersion solution containing the catalyst and the precursor (S36), the nickel-oxide nanoparticle dispersion solution is stirred for 1 hour and 30 minutes, using ultrasonic waves. At the step of centrifuging the nickel-oxide nanoparticle dispersion solution containing the catalyst and the precursor, and removing the solvent (S37, a fourth step), ethanol serving as the solvent is removed with a centrifugal separator. At the step of rinsing with alcohol (S38), rinsing is carried out once or more using, for example, ethanol. At the step of drying (S39), drying is carried out by heat treatment at, for example, 70° C. for 5 hours.

Note that, at each of the steps of stirring S32, S34, and S36, stirring may be carried out with, for example, a stirrer. Alternatively, stirring may be carried out with ultrasonic waves.

Furthermore, this embodiment exemplifies a case where, as described above, the steps of providing the coating portion 30 containing the inorganic oxide (S31 to S39) include steps of stirring three times in total. However, this embodiment shall not be limited to such a case. The number of the steps of stirring may be more than three, less than three, or zero.

Moreover, this embodiment exemplifies a case where, as described above, the step of adding the catalyst solution containing water and the catalyst for hydrolysis reaction (S33) and the step of adding the precursor solution containing the alcohol solvent and the precursor of the inorganic oxide forming the coating portion 30 (S35) are carried out in the stated order. However, this embodiment shall not be limited to such a case. The step of adding the precursor solution containing the alcohol solvent and the precursor of the inorganic oxide forming the coating portion 30 (S35) may be carried out first, and then, the step of adding the catalyst solution containing water and the catalyst for hydrolysis reaction (S33) may be carried out.

In addition, this embodiment exemplifies a case where the steps of providing the coating portion 30 containing inorganic oxide (S31 to S39) includes both the step of centrifuging the nickel-oxide nanoparticle dispersion solution containing the catalyst and the precursor and removing the solvent (S37) and the step of rinsing with alcohol (S38). However, this embodiment shall not be limited to such a case. At least one of the step of centrifuging the nickel-oxide nanoparticle dispersion solution containing the catalyst and the precursor and removing the solvent (S37) or the step of rinsing with alcohol (S38) may be omitted.

Note that, at the steps of providing the coating portion 30 containing inorganic oxide (S31 to S39), an alcohol solvent (e.g., ethanol) is used as a common solvent. This is because an ethoxy group (OCH₂CH₃) of tetraethoxysilane (TEOS) is hydrophobic and less likely to mix with water added at the step of adding the catalyst solution containing water and the catalyst for hydrolysis reaction; whereas, the alcohol solvent mixes with both the hydrophobic ethoxy group (OCH₂CH₃) and water.

In this embodiment, the steps of providing the coating portion 30 containing inorganic oxide (S31 to S39) can gelatinize tetraethoxysilane (TEOS) serving as a precursor of the inorganic oxide forming the coating portion 30. At the step of stirring the nickel-oxide nanoparticle dispersion solution containing the catalyst and the precursor (S36), the gelatinization of tetraethoxysilane (TEOS) proceeds. However, when the solvent is removed at the step of centrifuging the nickel-oxide nanoparticle dispersion solution containing the catalyst and the precursor and removing the solvent (S37) and at the step of drying (S39), the gelatinization of tetraethoxysilane (TEOS) can further proceed.

As illustrated in FIG. 10, the coating portion 30 after the step of drying (S39) is made of a portion containing an O—Si—O bond as an inorganic oxide and a not-shown portion containing a residual ethoxy group (OCH₂CH₃) and a residual OH group bonded to Si. Such a coating portion 30 is formed of a porous inorganic oxide containing an inorganic group.

As illustrated in FIG. 10, the coating portion 30 formed of a porous inorganic oxide containing an organic group can reduce agglomeration of the nickel-oxide nanoparticles NP themselves having the surface oxygen-deficient portions DE and keep a distance between the nickel-oxide nanoparticles NP.

As shown in FIGS. 9 and 10, the step of heat-treating the nickel-oxide nanoparticles NP as a plurality of metal-oxide nanoparticles is carried out (S40). Here, the step is carried out under an oxygen atmosphere while the coating portion 30, which is formed of a porous inorganic oxide containing an organic group, keeps a distance between the nickel-oxide nanoparticles NP having the surface oxygen-deficient portions DE.

This embodiment shows a case where, as illustrated in FIG. 10, the heat treatment is carried out with oxygen O₂ supplied at a predetermined flow rate at the step of heat-treating, under an oxygen atmosphere, the nickel-oxide nanoparticles NP as a plurality of metal-oxide nanoparticles (S40). However, this embodiment shall not be limited to such a case. The heat treatment may also be carried out in the air; that is, under an oxygen atmosphere.

When the heat treatment is carried out with oxygen O₂ supplied at a predetermined flow rate, the flow rate is adjusted appropriately so that a composition ratio of nickel elements to oxygen elements contained in the nickel-oxide nanoparticles NP′ can be set to 1:1.

Under an oxygen atmosphere, at the step of heat-treating the nickel-oxide nanoparticles NP as a plurality of metal-oxide nanoparticles (S40) as described above, the coating portion 30 is formed of a porous inorganic oxide containing an organic group. Such a feature makes it possible to smoothly supply oxygen O₂ to the surface oxygen-deficient portions DE of the nickel-oxide nanoparticles NP so that the surface oxygen-deficient portions DE can be repaired. As a result, the obtained nickel-oxide nanoparticles NP′ as a plurality of metal-oxide nanoparticles are successfully free from the surface oxygen-deficient portions DE.

Furthermore, under an oxygen atmosphere, at the step of heat-treating the nickel-oxide nanoparticles NP as a plurality of metal-oxide nanoparticles (S40), the heat treatment is preferably carried out at a temperature of 500° C. or higher for 3 hours or more. When the heat treatment is given at a temperature of 500° C. or higher for 3 hours or more, the coating portion 30 can be formed of silicon oxide as the inorganic oxide. Such a feature can increase reliability even if the coating portion 30 is at least partially left unremoved.

As shown in FIGS. 9 and 10, after the step of heat-treating (S40), at the step of removing the coating portion 30 (S41), the nickel-oxide nanoparticles NP′ as a plurality of metal-oxide nanoparticles are rinsed with an alkali solution. Hence, the coating portion 30 can be removed. The alkaline solution may be, for example, a NaOH aqueous solution. When a concentration of the alkali solution, a count of rinse with the alkali solution, and a time period in which the nickel-oxide nanoparticles NP′ are in contact with the alkali solution are controlled appropriately, the number of remaining coating portions 30 can be adjusted appropriately.

As illustrated in FIG. 11, as to the hole transport layer 24HT serving as a charge transport layer included in each of the red light-emitting element 5R, the green light-emitting element 5G, and the blue light-emitting element 5B included in the display device 1 of the first embodiment, a portion of nickel-oxide nanoparticles NP′ included in the plurality of nickel-oxide nanoparticles NP′ may have the surface SU at least partially provided with the coating portion 30.

Assuming that FIG. 11 is a cross-sectional view of the hole transport layer 24HT in a predetermined size, if A represents a total number of the nickel-oxide nanoparticles NP′ included in the cross-section in the predetermined size and B represents the number of the nickel-oxide nanoparticles NP′ included in the cross-section in the predetermined size and provided with the coating portion 30, (B/A) is preferably 0.1 or less. In FIG. 11, A is 11, B is 1, and (B/A) is 0.09. Note that if a portion of a nickel-oxide nanoparticle NP′ is included in the cross-section in the predetermined size, the portion is counted as one nickel-oxide nanoparticle NP′. If the coating portion 30 alone is included in the cross-section in the predetermined size, the coating portion 30 is counted as a nickel-oxide nanoparticle NP′ provided with the coating portion 30.

Each of the red light-emitting element 5R, the green light-emitting element 5G, and the blue light-emitting element 5B including the hole transport layer 24HT illustrated in FIG. 11, and the display device 1 including the red light-emitting element 5R, the green light-emitting element 5G, and the blue light-emitting element 5B successfully achieve high reliability and reduce a decrease in light emission efficiency accompanied by a decrease in external quantum efficiency (EQE).

### Second Embodiment

Described next is a second embodiment of the disclosure, with reference to FIGS. 12 and 13. A red light-emitting element 5R′ of this embodiment is different from the red light-emitting element 5R of the first embodiment described above in that the red light-emitting element 5R′ includes an electron transport layer 24ET′ containing zinc-oxide nanoparticles NP1′ as a plurality of metal-oxide nanoparticles free from the surface oxygen-deficient portions DE. Otherwise, the red light-emitting element 5R′ is the same as the red-light emitting element 5R of the first embodiment. For convenience in description, like reference signs designate identical constituent features throughout the drawings between this embodiment and the first embodiment. These constituent features will not be elaborated upon.

FIG. 12 is a cross-sectional view illustrating a schematic configuration of the red light-emitting element 5R′ included in the display device according to the second embodiment.

FIG. 13 is a cross-sectional view illustrating a schematic configuration of the electron transport layer 24ET′ serving as a charge transport layer included in the red light-emitting element 5R′ in FIG. 12.

The red light-emitting element 5R′ illustrated in FIG. 12 includes the electron transport layer 24ET′ containing the zinc-oxide nanoparticles NP1′ as a plurality of metal-oxide nanoparticles free from the surface oxygen-deficient portions DE. Note that, when the zinc-oxide nanoparticles are heat-treated with oxygen O₂ supplied at a predetermined flow rate, the flow rate is adjusted appropriately so that a composition ratio of metal elements (zinc elements) to oxygen elements contained in the zinc-oxide nanoparticles NP′ can be set to 1:1. This embodiment exemplifies a case where the zinc-oxide nanoparticles NP1′ are used. However, this embodiment shall not be limited to such a case. For example, magnesium-zinc-oxide nanoparticle may be used. Note that, when the magnesium-zinc-oxide nanoparticles are heat-treated with oxygen O₂ supplied at a predetermined flow rate, the flow rate is adjusted appropriately so that a composition ratio of metal elements (zinc elements and magnesium elements) to oxygen elements contained in the magnesium-zinc-oxide nanoparticles can be set to 1:1. The electron transport layer 24ET′ may be formed to have a thickness of, for example, 30 nm or more and 120 nm or less. However, the thickness shall not be limited to such an example.

Furthermore, the hole transport layer 24ET′ included in the red light-emitting element 5R′ illustrated in FIG. 12 can be formed of, for example, the nickel-oxide nanoparticles NP having the surface oxygen-deficient portions DE. Note that the hole transport layer 24HT′ may be formed to have a thickness of, for example, 10 nm or more and 150 nm or less. However, the thickness shall not be limited to such an example.

As illustrated in FIG. 13, as to the electron transport layer 24HT′ serving as a charge transport layer included in the red light-emitting element 5R′ included in the display device 2 of the second embodiment, a portion of zinc-oxide nanoparticles NP1′ included in the plurality of zinc-oxide nanoparticles NP1′ may have the surface SU at least partially provided with the coating portion 30.

Assuming that FIG. 13 is a cross-sectional view of the electron transport layer 24HT′ in a predetermined size, if A represents a total number of the zinc-oxide nanoparticles NP1′ included in the cross-section in the predetermined size and B represents the number of the zinc-oxide nanoparticles NP1′ included in the cross-section in the predetermined size and provided with the coating portion 30, (B/A) is preferably 0.1 or less. In FIG. 13, A is 11, B is 1, and (B/A) is 0.09. Note that if a portion of a zinc-oxide nanoparticle NP1′ is included in the cross-section in the predetermined size, the portion is counted as one zinc-oxide nanoparticle NP1′. If the coating portion 30 alone is included in the cross-section in the predetermined size, the coating portion 30 is counted as a zinc-oxide nanoparticles NP1′ provided with the coating portion 30.

The red light-emitting element 5R′ including the electron transport layer 24ET′ illustrated in FIG. 13 and the display device 2 including the red light-emitting element 5R′ successfully achieve high reliability and reduce a decrease in light emission efficiency accompanied by a decrease in external quantum efficiency (EQE).

### Third Embodiment

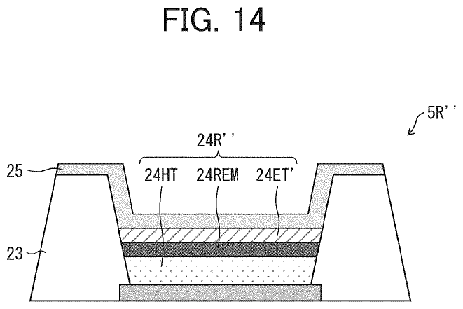

Described next is a third embodiment of the disclosure, with reference to FIG. 14. A red light-emitting element 5R″ of this embodiment is different from the red light-emitting element 5R of the first embodiment and the red light-emitting element 5R′ of the second embodiment described above in that the red light-emitting element 5R″ includes: the hole transport layer 24HT containing the nickel-oxide nanoparticles NP′ as a plurality of metal-oxide nanoparticles free from the surface oxygen-deficient portions DE; and the electron transport layer 24ET′ containing the zinc-oxide nanoparticles NP1′ as a plurality of metal-oxide nanoparticles free from the surface oxygen-deficient portions DE. Otherwise, the red light-emitting element 5R″ is the same as the red light-emitting element 5R′ of the first embodiment and the red light-emitting element 5R″ of the second embodiment. For convenience in description, like reference signs designate identical constituent features throughout the drawings between this embodiment and the first and second embodiments. These constituent features will not be elaborated upon.

FIG. 14 is a cross-sectional view illustrating a schematic configuration of the red light-emitting element 5R″ included in the display device according to the third embodiment.

As illustrated in FIG. 14, the red light-emitting element 5R″ includes: the hole transport layer 24HT serving as a charge transport layer (a first charge transport layer) containing the nickel-oxide nanoparticles NP′ as a plurality of metal-oxide nanoparticles free from the surface oxygen-deficient portions DE; and the electron transport layer 24ET′ serving as a charge transport layer (a second charge transport layer) containing the zinc-oxide nanoparticles NP1′ as a plurality of second metal-oxide nanoparticles free from the surface oxygen-deficient portions DE.

The red light-emitting element 5R″ including the hole transport layer 24HT and the electron transport layer 24ET′ illustrated in FIG. 14, and the display device including the red light-emitting element 5R″, successfully achieve higher high reliability and further reduce a decrease in light emission efficiency accompanied by a decrease in external quantum efficiency (EQE).

### Additional Remarks

The disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the disclosure. Moreover, the technical aspects disclosed in each embodiment may be combined together to achieve a new technical feature.

### INDUSTRIAL APPLICABILITY

The disclosure is applicable to a light-emitting element, a display device, a method for manufacturing the light-emitting element, and a method for manufacturing metal-oxide nanoparticles.

1. A light-emitting element, comprising:
an anode;
a cathode;
a light-emitting layer provided between the anode and the cathode; and
a charge transport layer provided between one of the anode or the cathode and the light-emitting layer,
wherein the charge transport layer contains a plurality of metal-oxide nanoparticles free from surface oxygen-deficient portions, and
one or more metal-oxide nanoparticles included in the plurality of metal-oxide nanoparticles have a surface at least partially provided with a coating portion formed of inorganic oxide.

2. The light-emitting element according to claim 1,
wherein a portion of metal-oxide nanoparticles included in the plurality of metal-oxide nanoparticles has a surface at least partially provided with the coating portion.

3. The light-emitting element according to claim 2,
wherein if A represents a total number of the metal-oxide nanoparticles included in a cross-section of the charge transport layer in a predetermined size, and
B represents a number of metal-oxide nanoparticles included in the cross-section of the charge transport layer in the predetermined size and provided with the coating portion,
(B/A) is 0.1 or less.

4. The light-emitting element according to claim 1,
wherein the coating portion is formed of silicon oxide.

5. The light-emitting element according to claim 1,
wherein the charge transport layer is at least one of a hole transport layer or a hole injection layer provided between the anode and the light-emitting layer, and
the metal-oxide nanoparticles are a hole transport material.

6. The light-emitting element according to claim 5,
wherein the metal-oxide nanoparticles are metal-oxide nanoparticles containing at least one of Ni, Mg, Mo, Cu, Co, Cr, or Ti.

7. The light-emitting element according to claim 6,
wherein the metal-oxide nanoparticles are nickel-oxide nanoparticles.

8. The light-emitting element according to claim 7,
wherein a composition ratio of nickel elements to oxygen elements contained in the nickel-oxide nanoparticles is 1:1.

9. The light-emitting element according to claim 1,
wherein the charge transport layer is at least one of an electron transport layer or an electron injection layer provided between the cathode and the light-emitting layer, and
the metal-oxide nanoparticles are an electron transport material.

10. The light-emitting element according to claim 9,
wherein the metal-oxide nanoparticles are metal-oxide nanoparticles containing at least one of Zn, Mg, Ti, Si, Sn, W, Ta, Ba, Zr, Al, Y, or Hf.

11. The light-emitting element according to claim 10,
wherein the metal-oxide nanoparticles are zinc-oxide nanoparticles or magnesium-zinc-oxide nanoparticles.

12. The light-emitting element according to claim 11,
wherein a composition ratio of metal elements contained either in the zinc-oxide nanoparticles or in the magnesium-zinc-oxide nanoparticles to oxygen elements is 1:1.

13. The light-emitting element according to claim 5, further comprising
a second charge transport layer,
wherein the second charge transport layer is at least one of an electron transport layer or an electron injection layer provided between the cathode and the light-emitting layer,
the second charge transport layer contains a plurality of second metal-oxide nanoparticles free from surface oxygen-deficient portions,
the second metal-oxide nanoparticles are an electron transport material, and
one or more second metal-oxide nanoparticles included in the plurality of second metal-oxide nanoparticles have a surface at least partially provided with the coating portion formed of inorganic oxide.

14. A display device including the light-emitting element according to claim 1.

15. A method for manufacturing a light-emitting element, the method comprising
a step of forming a charge transport layer including:
a step of providing a coating portion, containing inorganic oxide, to a surface of each of a plurality of metal-oxide nanoparticles; and
after the step of providing the coating portion, a step of heat-treating the plurality of metal-oxide nanoparticles under an oxygen atmosphere.

16. The method for manufacturing the light-emitting element according to claim 15,
wherein the step of forming the charge transport layer includes a step of removing the coating portion after the step of heat-treating.

17. The method for manufacturing the light-emitting element according to claim 16,
wherein, at the step of removing the coating portion, the plurality of metal-oxide nanoparticles is rinsed with an alkali solution.

18-27. (canceled)

28. A method for manufacturing metal-oxide nanoparticles, the method comprising:
a step of providing a coating portion, containing inorganic oxide, to a surface of each of a plurality of metal-oxide nanoparticles; and
after the step of providing the coating portion, a step of heat-treating the plurality of metal-oxide nanoparticles under an oxygen atmosphere.

29. The method for manufacturing the metal-oxide nanoparticles according to claim 28, further comprising
a step of removing the coating portion after the step of heat-treating.

30. The method for manufacturing the metal-oxide nanoparticles according to claim 28,
wherein the metal-oxide nanoparticles to be used at the step of providing the coating portion are nickel-oxide nanoparticles.
